(19) United States
(12) Patent Application Publication
(10) Pub. No.: US 2020/0335466 A1
(43) Pub. Date: Oct. 22, 2020

(54) CENTRIPETAL BUMPING LAYOUT AND METHOD

(71) Applicants: STMicroelectronics (Alps) SAS, Grenoble (FR); STMicroelectronics (Grenoble 2) SAS, Grenoble (FR)

(72) Inventors: Laurent SCHWARTZ, La buisse (FR); David KAIRE, Montaud (FR); Jerome LOPEZ, Saint Joseph de Riviere (FR)

(73) Assignees: STMicroelectronics (Alps) SAS, Grenoble (FR); STMicroelectronics (Grenoble 2) SAS, Grenoble (FR)

(21) Appl. No.: 16/847,934

(22) Filed: Apr. 14, 2020

(30) Foreign Application Priority Data
Apr. 18, 2019 (FR) 1904169
Dec. 9, 2019 (FR) 1913917

(51) Int. Cl. H01L 23/00

(52) U.S. Cl. CPC H01L 24/14; H01L 24/13; H01L 24/05; H01L 24/16; H01L 2224/11334; H01L 2224/14142; H01L 2224/13014; H01L 2224/0401; H01L 2224/16227; H01L 24/11

(57) ABSTRACT

A bumping matrix includes many bumps, wherein each bump is rotationally asymmetric in a plane of the bumping matrix. The bumps are orientated in a centripetal arrangement. Bumps in a first portion of the bumping matrix have a first pitch in a first axis and bumps in a second portion of the bumping matrix have a second pitch in the first axis. The second pitch is different from the first pitch. Bumps have an oblong shape with a longer diameter and a shorter diameter. The centripetal arrangement orients the longer diameter of the bumps is a direction radially extending from a center of the bumping matrix.

### PRIORITY CLAIM

This application claims the priority benefit of French Application for Patent No. 1904169, filed on Apr. 18, 2019, and claims the priority benefit of French Application for Patent No. 1913917, filed on Dec. 9, 2019, the contents of which are hereby incorporated by reference in their entireties to the maximum extent allowable by law.

### TECHNICAL FIELD

The present disclosure relates generally to the field of integrated circuit chips, and in particular to a flip chip assembly and a substrate using bumps to form electrical connections with the chip, and to a method of circuit conception for generating a bump layout.

### BACKGROUND

A bumping matrix is often used to electrically connect integrated circuit chips to a substrate, such as a PCB (printed circuit board). The bumping matrix comprises an array of regularly spaced solder bumps that electrically connect aligned input/output (I/O) pads on the integrated circuit chip and on the substrate. In the integrated circuit chip, the I/O pads are generally formed over the metal interconnection layers of the chip, and the chip is thus flipped over before being mounted to the substrate. Such an assembly is therefore often referred to as a flip chip assembly.

In order to improve electrical and thermal performance, it would be desirable to increase the bump density of the bumping matrix. However, reducing the pitch between bumps can lead to a high rate of short circuits occurring between neighboring bumps, which is undesirable. Furthermore, reducing the bump size can lead to a higher risk of so-called “time zero” or “reliability failures” linked to higher stress in each bump and under each bump, in other words within the silicon of the integrated circuit chip.

There is thus a need in the art for an improved type of bumping matrix and method of conception for such a bumping matrix.

### SUMMARY

According to one aspect, a bumping matrix comprises bumps, each bump being rotationally asymmetric in the plane of the bumping matrix, the bumps being orientated in a centripetal arrangement, wherein the bumps in a first portion of the bumping matrix have a first pitch in a first axis and the bumps in a second portion of the bumping matrix have a second pitch in the first axis, the second pitch being different to the first pitch.

According to one embodiment, the bumps are formed in concentric rings or concentric partial rings.

According to one embodiment, at least some of the bumps are formed in a first annular zone and at least some of the bumps are formed in a second annular zone, the first and second annular zones being concentric.

According to one embodiment, each of the first and second annular zones comprises a plurality of rings, or partial rings, of bumps.

According to a further aspect, there is provided a circuit having a contact surface comprising connection pads to be coupled to a bumping matrix, wherein each connection pad has an exposed surface area that is rotationally asymmetric in the plane of the contact surface, the connection pads being orientated in a centripetal arrangement, wherein the connection pads in a first portion of the contact surface have a first pitch in a first axis and the connection pads in a second portion of the contact surface have a second pitch in the first axis, the second pitch being different to the first pitch.

According to one embodiment, the circuit is an integrated circuit chip.

According to one embodiment, the circuit is a substrate for receiving an integrated circuit chip.

According to yet a further aspect, there is provided a flip-chip assembly comprising the above circuit; a further circuit; and the above bumping matrix connecting the connections pads of the circuit to connection pads on a contact surface of the further circuit.

According to a further aspect, there is provided a method of circuit conception implemented by a processing device under control of software instructions, the method comprising: defining dimensions of each bump in the plane of a contact surface defined by a circuit design; and automatically performing placement of bumps on the contact surface such that the bumps are orientated on the contact surface in a centripetal arrangement, and such that the bumps in a first portion of the contact surface have a first pitch in a first axis and the bumps in a second portion of the contact surface have a second pitch in the first axis, the second pitch being different to the first pitch.

According to one embodiment, the bumps are placed in concentric rings or concentric partial rings.

According to one embodiment, at least some of the bumps are placed in a first annular zone and at least some of the bumps are placed in a second annular zone, the first and second annular zones being concentric.

According to one embodiment, each of the first and second annular zones comprises a plurality of concentric rings, or concentric partial rings, of bumps.

According to one embodiment, the second annular zone is radially outside the first annular zone and comprises a greater number of concentric rings or concentric partial rings than the first annular zone.

According to yet a further aspect, there is provided a non-transitory computer-readable memory device storing computer instructions that cause the implementation of the above method when executed by a processing device.

According to one embodiment, there is a variable safety sizing around the bumps.

According to one embodiment, there is a translation of the bumps into a 2D shape.

According to one embodiment, there is a circular orientation of the bumps.

According to one embodiment, the bump placement is automated.

According to one aspect, there is provided a substrate comprising a contact surface having bumps formed thereon, each bump being rotationally asymmetric in the plane of the contact surface, the bumps for example being orientated on the contact surface in a centripetal arrangement, wherein the bumps in a first zone of the contact surface have a first pitch in a first axis and the bumps in a second zone of the contact surface have a second pitch in the first axis, the second pitch being different to the first pitch.

According to one embodiment, a bump density in the first zone is different from a bump density in the second zone.

According to one embodiment, there is an exclusion zone around each of the bumps in which no other bump is formed, wherein the exclusion zone for example has a first width in a first axis and a second width in a second axis perpendicular to the first axis, the first and second widths being different from each other.

According to one embodiment, the exclusion zone is hexagonal or substantially hexagonal.

According to one embodiment, each bump is oblong in shape, or substantially oblong in shape.

According to a further aspect, there is provided a substrate comprising a contact surface having bumps formed thereon, each bump being rotationally asymmetric in the plane of the contact surface, the bumps for example being orientated on the contact surface in a centripetal arrangement, wherein the centers of the bumps are positioned in a first pattern in a first zone of the contact surface and in a second pattern, different to the first pattern, in a second zone of the contact surface, the first and second patterns for example defining the spacing between the centers of the bumps in the plane of the contact surface.

According to one embodiment, the first zone is a central zone of the contact surface, and the second zone is an annular zone surrounding the central zone.

According to a further aspect, there is provided a substrate comprising a contact surface having bumps formed thereon, each bump being rotationally asymmetric in the plane of the contact surface, the bumps for example being orientated on the contact surface in a centripetal arrangement, wherein the bumps are positioned such that the centers of the bumps in the plane of the contact surface are not aligned.

According to a further aspect, there is provided a method of circuit conception implemented by a processing device under control of software instructions, the method comprising:
defining dimensions of each bump in the plane of a contact surface defined by a circuit design; and
automatically performing placement of bumps on the contact surface such that the bumps are for example orientated on the contact surface in a centripetal arrangement, and/or such that the bumps in a first zone of the contact surface have a first pitch in a first axis and the bumps in a second zone of the contact surface have a second pitch in the first axis, the second pitch being different to the first pitch.

According to a further aspect, there is provided a method of circuit conception implemented by a processing device under control of software instructions, the method comprising:
defining dimensions of each bump in the plane of a contact surface defined by a circuit design; and
automatically performing placement of bumps on the contact surface such that the bumps are for example orientated on the contact surface in a centripetal arrangement, and/or such that the centers of the bumps are positioned in a first pattern in a first zone of the contact surface and in a second pattern, different to the first pattern, in a second zone of the contact surface, the first and second patterns for example defining the spacing between the centers of the bumps in the plane of the contact surface.

According to a further aspect, there is provided a method of circuit conception implemented by a processing device under control of software instructions, the method comprising:
defining dimensions of each bump in the plane of a contact surface defined by a circuit design; and
automatically performing placement of bumps on the contact surface such that the bumps are for example orientated on the contact surface in a centripetal arrangement, and/or such that the bumps are positioned such that the centers of the bumps in the plane of the contact surface are not aligned.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a plan view of part of a bumping matrix having regularly spaced oblong bumps orientated in a centripetal fashion;

FIG. 2 represents, in plan view, an oblong bump and an exclusion zone;

FIG. 3 is a plan view of a bumping matrix;

FIG. 4 illustrates part of the bumping matrix of FIG. 3 in more detail;

FIG. 5 is a cross-section view of a flip-chip assembly comprising a bumping matrix;

FIG. 6 is a cross-section view illustrating one bump of the bumping matrix of FIG. 6 in more detail;

FIG. 7 schematically illustrates a computing device for circuit conception;

FIG. 8 is a flow diagram representing operations in a method of circuit conception; and

FIG. 9 is a plan view of a bumping matrix divided into zones for simulation purposes.

### DETAILED DESCRIPTION

Like features have been designated by like references in the various figures. In particular, the structural and/or functional features that are common among the various embodiments may have the same references and may dispose identical structural, dimensional and material properties.

Unless indicated otherwise, when reference is made to two elements connected together, this signifies a direct connection without any intermediate elements other than conductors, and when reference is made to two elements linked or coupled together, this signifies that these two elements can be connected or they can be linked or coupled via one or more other elements.

In the following disclosure, unless indicated otherwise, when reference is made to absolute positional qualifiers, such as the terms “front”, “back”, “top”, “bottom”, “left”, “right”, etc., or to relative positional qualifiers, such as the terms “above”, “below”, “higher”, “lower”, etc., or to qualifiers of orientation, such as “horizontal”, “vertical”, etc., reference is made to the orientation shown in the figures.

Unless specified otherwise, the expressions “around”, “approximately”, “substantially” and “in the order of” signify within 10%, and preferably within 5%.

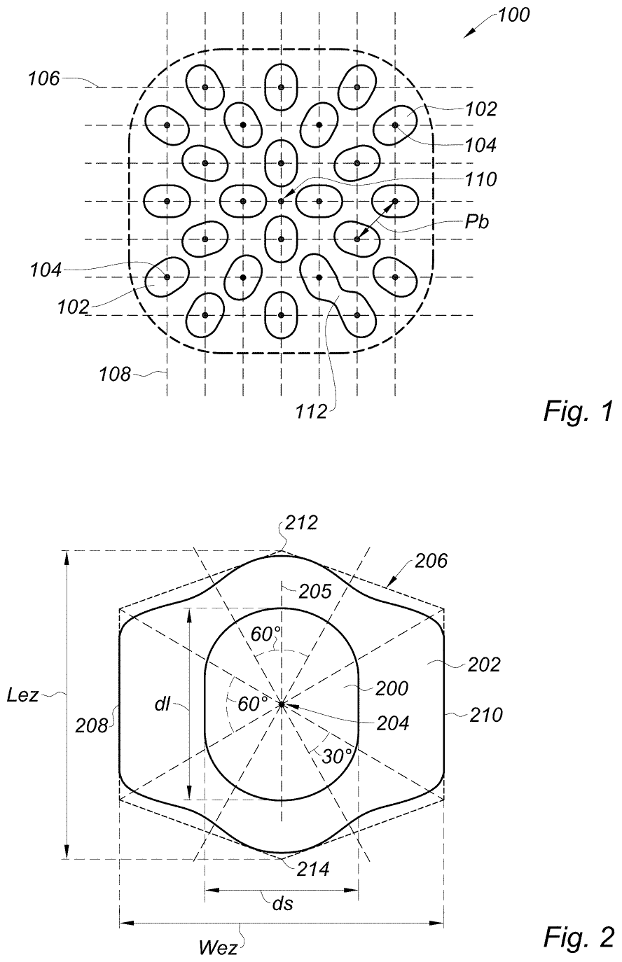

FIG. 1 is a plan view of part of a bumping matrix 100 having regularly spaced oblong bumps 102 orientated in a centripetal fashion.

The bumps 102 in the example of FIG. 1 are regularly spaced in that a center of each bump is positioned at a point 104, the points 104 being aligned at the intersections of row lines 106 and column lines 108. In the example of FIG. 1, bumps are positioned at alternate intersections of the row and column lines 106, 108, in other words in a checkerboard pattern with respect to these intersections.

Each of the bumps 102 is oblong in shape, and in order to reduce stress, the bumps 102 are orientated in a centripetal arrangement around a central point 110 of the matrix. However, a difficulty of such an arrangement is that, when the bump pitch is relatively low, there is a risk of short circuits between neighboring bumps. An example of such a short circuit is shown by fused bumps 112 in FIG. 1.

The bump pitch Pb is, for example, defined as the closest distance between the centers of adjacent bumps, which in the example of FIG. 1 corresponds to the distance between diagonally adjacent intersections of row and column lines.

The present inventors have found that, for an arrangement of the type of FIG. 1, the risk of short circuits between bumps is highest close to the edges of the matrix, where the bumps are orientated in a similar fashion and a longer dimension of the oblong shape for the bumps extends generally in a diagonal direction relative to the rows/columns.

In order to provide a relatively high bump density and low risk of short circuits, the present inventors propose a bumping matrix in which the bumps are no longer regularly spaced (i.e., at alternate intersections of rows/columns), but are instead irregularly spaced while respecting an exclusion zone around each bump, as will now be described in more detail with reference to FIG. 2.

FIG. 2 represents, in plan view, an oblong bump 200 surrounded by an exclusion zone 202 according to an example embodiment of the present disclosure.

The bump 200 in the example of FIG. 2 is stadium-shaped, in other words where an outer perimeter of the bump corresponds to two facing semi-circles joined by straight lines. Thus, each bump possesses a longer dimension (in the illustration, extending vertically and comprising the longer diameter dl of the bump) and a smaller dimension (in the illustration, extending horizontally and comprising the shorter diameter ds of the bump).

The exclusion zone 202 is, for example, defined as a distance from the center 204 of the bump 200, although in alternative embodiments it could be defined as a distance from the outer peripheral edge of the bump 200. In embodiments described below, the exclusion zone 202 is a zone in which another bump should not be placed, and which should not overlap with the exclusion zone of another bump. It would also be possible to define an exclusion zone as a zone in which another bump should not be placed, but which can overlap with the exclusion zone of another bump. Those skilled in the art will understand how the examples provided below could be adapted to such an alternative definition of the exclusion zone.

The exclusion zone 202, for example, has different dimensions in different axes extending through the center of the bump. In some embodiments, the exclusion zone 202 has a length Lez in the axis 205 of the longest diameter dl of the bump 200 (i.e., the longer dimension) that is greater than the width Wez in the axis (not illustrated) perpendicular to the axis 205, corresponding to the axis of the shortest diameter ds of the bump (i.e., the smaller dimension).

In some embodiments, the exclusion zone is substantially hexagonal, as represented by a dotted hexagon 206 of FIG. 2. Opposite edges 208, 210 of the hexagon are aligned parallel with the axis of the longest diameter of the bump 200, and are separated by the exclusion zone width Wez. Opposite vertices 212, 214 of the hexagon are on the axis of the longest diameter of the bump 200, and separated by the exclusion zone length Lez.

In alternative embodiments, the exclusion zone 202 is defined by a curve that respects minimum distances from the center 204 of the bump 200, or from the edge of the bump 200, the minimum distances being different in different sectors. For example, defining 0° as the axis 205 on one side of the bump 200, the exclusion zone 202 for example has:

a minimum distance D1, from the center 204, in the sectors from 330° to 30° and from 150° to 210°;

a minimum distance D2, from the center 204, in the sectors from 30° to 60°, from 120° to 150°, from 210° to 240°, and from 300° to 330°; and

a minimum distance D3, from the center 204, in the sectors from 60° to 120° and from 240° to 300°.

In some embodiments, for a bump having a longest diameter dl, the length Lez/2, and/or distance D1, is, for example, in the range 0.7*dl to 1.1*dl, and for a bump having a shortest diameter ds, the width Wez/2, and/or distance D3, is, for example, in the range 1.5*ds to 2*ds. The distance D2 is, for example, between the distances D1 and D3, in other words D3≤D2≤D1.

In one example, dl is between 60 and 100 μm and, for example, substantially equal to 80 μm, ds is between 40 and 80 μm, and, for example, substantially equal to 62 μm, the length Lez/2, and/or distance D1, is in the range 60 to 100 μm, and, for example, substantially equal to 76 μm, and the width Wez/2, and/or distance D3, is in the range 90 to 120 μm and, for example, substantially equal to 101 μm.

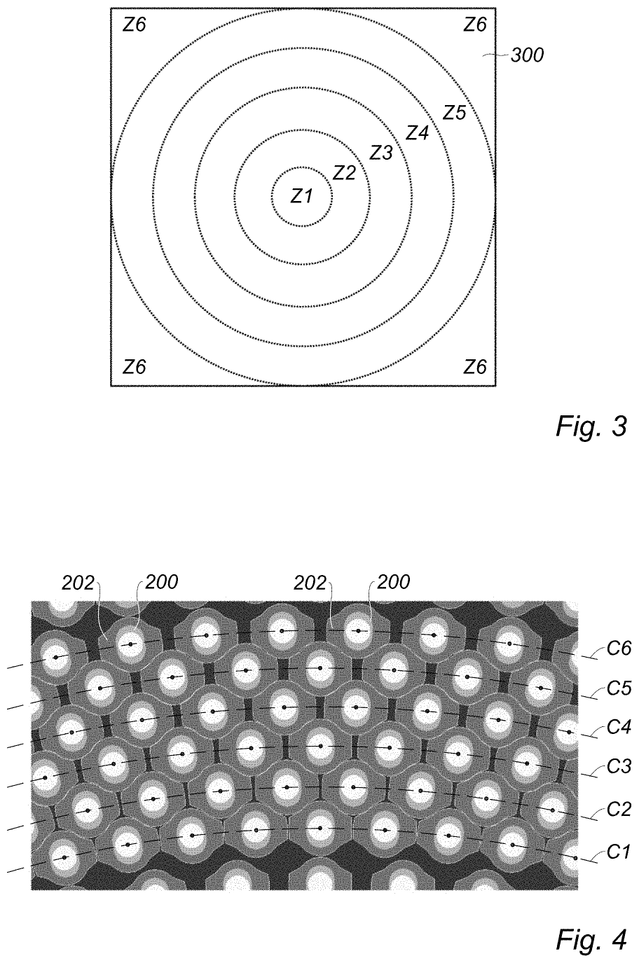

FIG. 3 is a plan view of a bumping matrix 300 according to an example embodiment of the present disclosure. For example, FIG. 3 corresponds to a contact surface of an integrated circuit chip or substrate to be connected via a bumping matrix. The bumps (not shown in FIG. 3) are, for example, positioned in a central circular zone Z1, and in two or more concentric annular zones around the circular zone Z1, there being four such zones Z2 to Z5 in the example of FIG. 3. Bumps may also be formed in a zone between the outermost annular zone and the edges of the contact surface, which is, for example, rectangular. Such a zone is labelled Z6 in FIG. 3.

The bumps are, for example, positioned in a concentric rings, or concentric partial rings, in each of the zones Z1 to Z6, as will now be described with reference to FIG. 4.

FIG. 4 illustrates part of the bumping matrix of FIG. 3 in more detail according to an example embodiment of the present disclosure. In particular, FIG. 4 illustrates the bumps 200 with exclusion zones 202 positioned in the part of the annular zone Z5 of FIG. 4.

The bumps 200 are, for example, arranged such that their center points are positioned on one or more circles or arcs of circles, there being six circles or arcs C1 to C6 in the example of FIG. 4. Thus, the bumps 200, for example, form complete or partial rings. The bumps 200 are, for example, orientated in a centripetal arrangement, in other words with the axis of the longest diameter of each bump passing through or close to the center of the bumping matrix and/or of the integrated circuit chip. In other words, the longest diameter of each bump is oriented to extend in a radial direction away from the center of the bumping matrix and/or of the integrated circuit chip.

In some embodiments, each annular zone Z2 to Z5 of FIG. 3 comprises at least two rings of bumps and, for example, between two and twenty rings of bumps.

The bumps 200 are, for example, positioned so as to respect the exclusion zone 202 of each bump.

For example, in the inner most ring of bumps 200 in each annular zone, such as the ring formed on the circle or arc C1 in FIG. 4, the bumps are positioned as close as possible to the inner edge of the zone, and as close together as possible in the circumferential direction. Thus, it can be seen that, for the bumps formed on the circle or arc C1, the edges of exclusion zones of adjacent bumps meet, or are relatively close.

In the next ring of bumps 200, such as the ring formed on the circle or arc C2 in FIG. 4, each bump is, for example, positioned on a circle or arc that is as close as possible to the circle or arc C1, while respecting the exclusion zone. Thus, in view of the shape of the exclusion zone 202 of each bump 200, the bumps in one ring are, for example, misaligned in the circumferential direction with respect to those of an adjacent ring by around half the bump pitch in the circumferential direction.

The present inventors have found that, after a certain number of rings of bumps are placed in a given annular zone, the spacing between adjacent bumps in the circumferential direction has increased to such an extent that a greater bump density can be achieved by starting a new annular zone, in which the bumps are no longer constrained by an inner ring of bumps.

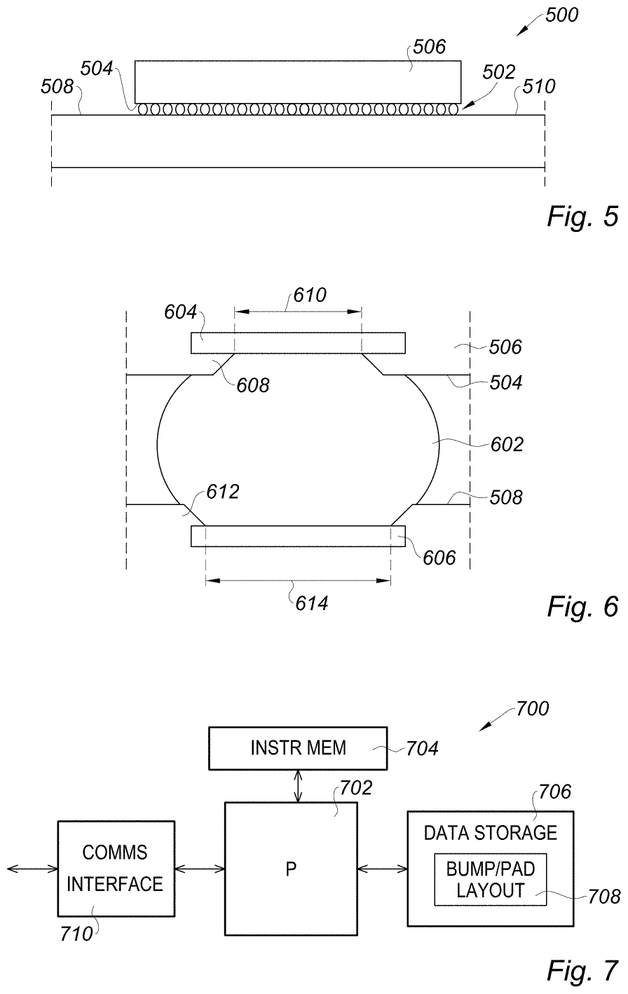

FIG. 5 is a cross-section view of a flip-chip assembly 500 comprising a bumping matrix 502 connecting pads formed in a contact surface 504 of an integrated circuit chip 506 to pads formed in a contact surface 508 of a substrate 510, which is, for example, a PCB. Thus, the bumping matrix 502 is used to interconnect the circuits 506 and 510.

FIG. 6 is a cross-section view illustrating one bump 602 of the bumping matrix 502 of FIG. 6 in more detail. A bump 602 contacts a pad 604 formed in the contact surface 504 of the integrated circuit chip 506, and also contacts a pad 606 formed in the contact surface 508 of the substrate 510. The pads 604, 606 are, for example, formed of Al, and the bump 602 is, for example, formed of a metal alloy, for example including Sn, forming a solder.

The pad 604 of the integrated circuit chip 506 is, for example, partially buried in a layer 608, for example of silicon nitride. The bump 602, for example, contacts the pad 604 in an opening 610 of the layer 608, where the surface of the pad 604 is exposed.

Similarly, on the substrate side, pad 606 is, for example, partially buried in a layer 612, for example of silicon nitride. The bump 602, for example, contacts the pad 606 in an opening 614 of the layer 612, where the surface of the pad 604 is exposed.

It is, for example, the position of each pad 604, 606 that defines the position of the bump. Therefore, the placement of the center of a bump at a given location is, for example, achieved by positioning a center of each of the pads 604, 606 at this location.

Furthermore, the shapes of the openings 610, 614, for example, define the shape that the bump 602 will take when soldered between the pads 604 and 606. In some embodiments, both of the openings 610, 614 are configured to have an elongated shape such that the resulting bump has an oblong or stadium-shaped form in a centripetal orientation (see, FIG. 2). In other embodiments, only one of the openings, such as the opening 614 on the substrate side, has an elongated shape, the opening 610 on the integrated circuit side for example having a square, hexagonal, circular or other shape.

FIG. 7 schematically illustrates a computing device 700 for circuit conception according to an example embodiment of the present disclosure.

The device 700, for example, comprises a processing device (P) comprising one or more processors under control of instructions stored in an instruction memory (INSTR MEM) 704 coupled to the processing device 702. Data storage (DATA STORAGE) 706 is also, for example, coupled to the processing device 702 or is otherwise accessible by the processing device 702. The data storage 706, for example, comprises one or more memory devices storing a bump or pad layout (BUMP/PAD LAYOUT) 708 defining the position of bumps or pads on a contact surface of an integrated circuit chip and/or substrate. The device 700 also, for example, comprises a communications interface (COMMS INTERFACE) 710 coupled to the processing device 702, via which the pad layout can, for example, be transmitted to a fabrication plant for manufacture.

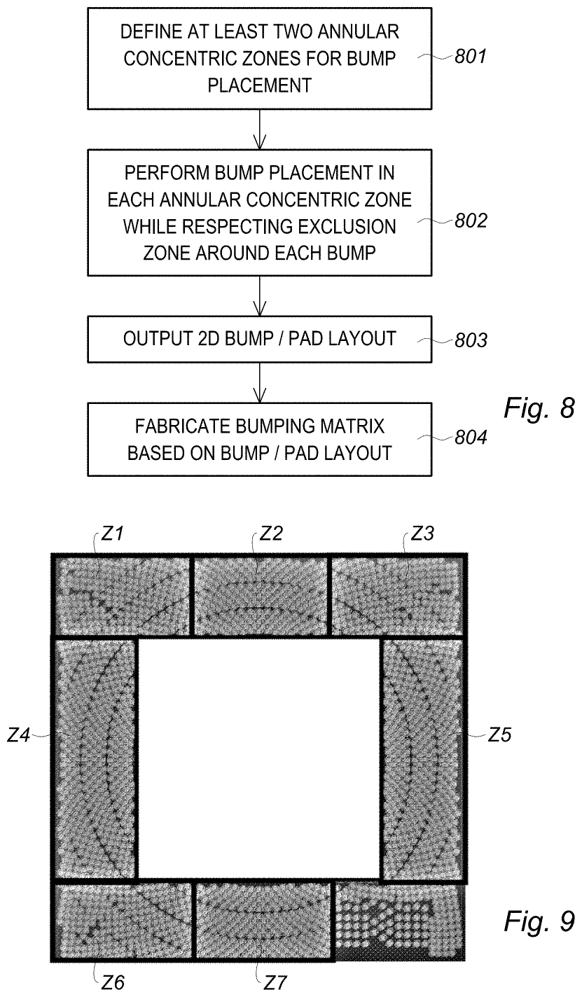

FIG. 8 is a flow diagram representing operations in a method of circuit conception according to an example embodiment of the present disclosure. Unless indicated otherwise, the operations of the method of FIG. 8 are, for example, implemented by the computing device 700 of FIG. 7.

In an operation 801, at least two annular concentric zones are for example defined for bump placement. Alternatively, the annular zones are defined in an adaptive manner, as described in more detail below.

In an operation 802, bump placement is, for example, performed in each annular concentric zone, while respecting the exclusion zone around each bump. For example, as described above with reference to FIG. 4, this is performed by placing the bumps in rings or ring portions, starting from an inner edge of each annular concentric zone.

In some embodiments, the sizing of and number of annular concentric zones is adaptive. For example, a first inner ring of bumps is placed, and then additional rings are added while ensuring a minimal distance between one ring and the next. However, when the bump pitch exceeds a certain threshold, a new annular zone is defined having an inner edge just outside last ring of bumps to be placed, and bump placement starts again in the new zone. Such a method, for example, results in concentric annular zones that comprises a greater number of concentric rings, or concentric partial rings, of bumps the further out they are from the center of the bumping matrix.

In an operation 803, a 2D bump or pad layout is generated based on the bump placement. For example, this layout is a file defining, in x and y coordinates, the position of the center of each bump, which corresponds to the position of the center of the corresponding pad of the contact surfaces to be connected.

In an operation 804, the layout is, for example, transmitted to a fabrication site and the bumping matrix is, for example, fabricated based on the layout.

FIG. 9 is a plan view of a bumping matrix divided into zones Z1 to Z7 for simulation purposes. Bump placement was simulated based on a manual placement of bumps in concentric annular zones each comprising five rings of bumps, and based on adaptive zone sizing as described above. The results for the zones Z1 to Z7 are shown in the following table.

TABLE 1

| | Number of | Number of Bumps - | Number of |
|---|---|---|---|
| | Bumps - | zones of five | bumps - |
| Zone | Manual | rings of bumps | adaptive |
| Z1 | 225 | 239 | 236 |
| Z2 | 226 | 237 | 237 |
| Z3 | 229 | 239 | 236 |
| Z4 | 397 | 426 | 434 |
| Z5 | 402 | 426 | 434 |
| Z6 | 225 | 239 | 242 |
| Z7 | 229 | 239 | 240 |
| Total | 1933 | 2045 | 2059 |

It can be seen that an automatic placement resulted in a significant increase in the number of bumps that could be placed in all of the zones, and the adaptive zone sizing method permitted a greater number of bumps to be placed overall.

Various embodiments and variants have been described. Those skilled in the art will understand that certain features of these embodiments can be combined and other variants will readily occur to those skilled in the art.

Finally, the practical implementation of the embodiments and variants described herein is within the capabilities of those skilled in the art based on the functional description provided hereinabove.

1. A bumping matrix, comprising:
a plurality of bumps;
wherein each bump is rotationally asymmetric in a plane of the bumping matrix;
said bumps being orientated in a centripetal arrangement;
wherein bumps in a first portion of the bumping matrix have a first pitch in a first axis and bumps in a second portion of the bumping matrix have a second pitch in the first axis, the second pitch being different from the first pitch.

2. The bumping matrix of claim 1, wherein the bumps are formed in a plurality of concentric rings.

3. The bumping matrix of claim 2, wherein the bumps are located in partial concentric rings.

4. The bumping matrix of claim 2, wherein each bump has an oblong shape including a longer diameter and a shorter diameter, and wherein all bumps located in a given concentric ring are oriented with the longer diameter extending in a radial direction away from a center of the bumping matrix.

5. The bumping matrix of claim 1, wherein first bumps of said plurality of bumps are located in a first annular zone and wherein second bumps of said plurality of bumps are located a second annular zone, the first and second annular zones being concentric.

6. The bumping matrix of claim 5, wherein each of the first and second annular zones comprises a plurality of rings.

7. The bumping matrix of claim 6, wherein the bumps are located in partial concentric rings.

8. The bumping matrix of claim 5, wherein each bump has an oblong shape including a longer diameter and a shorter diameter, and wherein all bumps of located in a given annular zone are oriented with the longer diameter extending in a radial direction away from a center of the bumping matrix.

9. The bumping matrix of claim 1, wherein each bump has an oblong shape including a longer diameter and a shorter diameter, and wherein all bumps of said plurality of bumps are oriented with the longer diameter extending in a radial direction away from a center of the bumping matrix.

10. A circuit, comprising:
a contact surface;
wherein the contact surface includes a plurality of connection pads to be coupled to a bumping matrix;
wherein each connection pad has an exposed surface area that is rotationally asymmetric in a plane of the contact surface;
said connection pads being orientated in a centripetal arrangement;
wherein connection pads in a first portion of the contact surface have a first pitch in a first axis and connection pads in a second portion of the contact surface have a second pitch in the first axis, the second pitch being different from the first pitch.

11. The circuit of claim 10, wherein the contact surface is a surface of an integrated circuit chip.

12. The circuit of claim 10, wherein the contact surface is a surface of a substrate configured an integrated circuit chip.

13. The circuit of claim 10, wherein the connection pads are formed in a plurality of concentric rings.

14. The circuit of claim 13, wherein the connection pads are located in partial concentric rings.

15. The circuit of claim 13, wherein each connection pad has an oblong shape including a longer diameter and a shorter diameter, and wherein all connection pads located in a given concentric ring are oriented with the longer diameter extending in a radial direction away from a center of the bumping matrix.

16. The circuit of claim 10, wherein first connection pads of said plurality of connection pads are located in a first annular zone and wherein second connection pads of said plurality of connection pads are located a second annular zone, the first and second annular zones being concentric.

17. The circuit of claim 16, wherein each of the first and second annular zones comprises a plurality of rings.

18. The circuit of claim 17, wherein the connection pads are located in partial concentric rings.

19. The circuit of claim 16, wherein each connection pad has an oblong shape including a longer diameter and a shorter diameter, and wherein all connection pads of located in a given annular zone are oriented with the longer diameter extending in a radial direction away from a center of the bumping matrix.

20. The circuit of claim 10, wherein each connection pad has an oblong shape including a longer diameter and a shorter diameter, and wherein all connection pads of said plurality of connection pads are oriented with the longer diameter extending in a radial direction away from a center of the bumping matrix.

21. A flip-chip assembly, comprising:
the circuit of claim 10;
a further circuit; and
wherein the bumping matrix connects the connections pads of the circuit to connection pads on a contact surface of the further circuit.

22. A method, comprising:
defining dimensions of each bump of a plurality of bumps in a bumping matrix in a plane of a contact surface defined by a circuit design;
wherein each bump is rotationally asymmetric in the plane; and
automatically performing placement of bumps on the contact surface such that the bumps are orientated on the contact surface in a centripetal arrangement, and such that the bumps in a first portion of the contact surface have a first pitch in a first axis and the bumps in a second portion of the contact surface have a second pitch in the first axis, the second pitch being different to the first pitch.

23. The method of claim 22, wherein the steps are defining and automatically performing placement are executed by a processing device under control of software instructions.

24. The method of circuit conception of claim 22, wherein the bumps are placed in concentric rings or concentric partial rings.

25. The method of circuit conception of claim 24, wherein at least some of the bumps are placed in a first annular zone and at least some of the bumps are placed in a second annular zone, the first and second annular zones being concentric.

26. The method of circuit conception of claim 25, wherein each of the first and second annular zones comprises a plurality of concentric rings, or concentric partial rings, of bumps.

27. The method of circuit conception of claim 25, wherein the second annular zone is radially outside the first annular zone and comprises a greater number of concentric rings or concentric partial rings than the first annular zone.

28. A non-transitory computer-readable memory device storing computer instructions that cause the implementation of the method of claim 22 when executed by a processing device.
